(19) United States
(12) Patent Application Publication
(10) Pub. No.: US 2024/0203784 A1
(43) Pub. Date: Jun. 20, 2024

(54) MEMBER FOR SEMICONDUCTOR MANUFACTURING APPARATUS

(71) Applicant: NGK INSULATORS, LTD., Nagoya-City (JP)

(72) Inventor: Hiroya SUGIMOTO, Chiryu-City (JP)

(73) Assignee: NGK INSULATORS, LTD., Nagoya-City (JP)

(21) Appl. No.: 18/342,810

(22) Filed: Jun. 28, 2023

Related U.S. Application Data
(63) Continuation of application No. PCT/JP2022/046693, filed on Dec. 19, 2022.

(51) Int. Cl. H01L 21/687; C23C 16/458; H01L 21/67

(52) U.S. Cl. CPC H01L 21/68785; C23C 16/4581; C23C 16/4586; H01L 21/67069; H01L 21/68757

(57) ABSTRACT

A member for semiconductor manufacturing apparatus includes a ceramic plate having a circular wafer placement surface having a seal band along an outer periphery, and an annular focus ring placement surface located outside the wafer placement surface and below the wafer placement surface; a circular inner heater electrode embedded in the ceramic plate; an annular outer heater electrode embedded in the ceramic plate and surrounding the inner heater electrode; and a cooling plate disposed at a surface of the ceramic plate opposite the wafer placement surface, wherein the inner heater electrode overlaps at least a portion of the seal band in plan view, and an outer diameter of the inner heater electrode is not less than 97% of an outer diameter of the wafer placement surface.

### BACKGROUND OF THE INVENTION

### 1. Field of the Invention

The present invention relates to a member for semiconductor manufacturing apparatus.

### Background Art

### 2. Description of the Related Art

A member for semiconductor manufacturing apparatus that holds a wafer during semiconductor manufacturing has been conventionally known. For example, PTL 1 discloses a member for semiconductor manufacturing apparatus in which a cooling plate is attached to a lower surface of a ceramic plate. The ceramic plate has a circular wafer placement surface having a seal band along the outer periphery and an annular stepped surface that is located outside the wafer placement surface and below the wafer placement surface. The ceramic plate internally has a circular inner heater electrode and an annular outer heater electrode surrounding the inner heater electrode. Both the inner heater electrode and the outer heater electrode do not overlap the seal band of the wafer placement surface in plan view.

### CITATION LIST

### Patent Literature

PTL 1: JP 2020-4928 A

### SUMMARY OF THE INVENTION

However, due to the absence of both the inner heater electrode and the outer heater electrode directly below the seal band, there is a risk of decrease in temperature of the outer circumferential area of the wafer that faces the seal band.

The present invention was made to solve the above-described problem, and the main object thereof is to increase the temperature uniformity of a wafer.
[1] A member for semiconductor manufacturing apparatus according to the present invention includes: a ceramic plate having a circular wafer placement surface having a seal band along an outer periphery and an annular focus ring placement surface located outside the wafer placement surface and below the wafer placement surface; a circular inner heater electrode embedded in the ceramic plate; an annular outer heater electrode embedded in the ceramic plate and surrounding the inner heater electrode; and a cooling plate disposed at a surface of the ceramic plate opposite the wafer placement surface, wherein the inner heater electrode overlaps at least a portion of the seal band in plan view, and an outer diameter of the inner heater electrode is not less than 97% of an outer diameter of the wafer placement surface.
In the member for semiconductor manufacturing apparatus, the inner heater electrode overlaps at least a portion of the seal band in plan view. Furthermore, the outer diameter of the inner heater electrode is not less than 97% of the outer diameter of the wafer placement surface. This increases the temperature uniformity of the wafer on the seal band of the wafer placement surface.
[2] In the member for semiconductor manufacturing apparatus according to the present invention (the member for semiconductor manufacturing apparatus described in the above [1]), the outer diameter of the inner heater electrode may be not less than 97% and not more than 103% of the outer diameter of the wafer placement surface. In this configuration, the inner heater electrode does not largely overlap the focus ring placement surface in plan view. Thus, the temperature of the focus ring is not largely affected by the inner heater electrode, making it easier for the outer heater electrode alone to control the temperature of the focus ring.
[3] In the member for semiconductor manufacturing apparatus according to the present invention (the member for semiconductor manufacturing apparatus described in the above [1] or [2]), a distance between an outer circumferential edge of the inner heater electrode and an inner circumferential edge of the outer heater electrode may be not less than 2 mm and not more than 18 mm. This can reliably provide the effect of the present invention.
[4] The member for semiconductor manufacturing apparatus according to the present invention (the member for semiconductor manufacturing apparatus described in any one of the above [1] to [3]) may further include a resin adhesive layer between the ceramic plate and the cooling plate. In this case, the heat transfer from the ceramic plate to the cooling plate is limited by the resin adhesive layer, which has a relatively low thermal conductivity, but the temperature uniformity of the wafer can be increased even in under such a circumstance.

### BRIEF DESCRIPTION OF THE DRAWINGS

FIG. 1 is a vertical cross-sectional view of a member for semiconductor manufacturing apparatus 10.

FIG. 2 is a plan view of a ceramic plate 20.

FIG. 3 is an explanatory view indicating examples of dimensions of the components.

FIG. 4 is a graph indicating a relationship between a distance from the center of the wafer and a temperature of the wafer.

FIG. 5 is a graph indicating a relationship between an outer diameter φ2 of an inner heater electrode and temperature variation of the wafer.

FIG. 6 is a graph indicating a relationship between a distance from the center of the wafer and a temperature of the wafer.

FIG. 7 is a graph indicating a relationship between a distance from the center of the wafer and a temperature of the wafer.

### DETAILED DESCRIPTION OF THE INVENTION

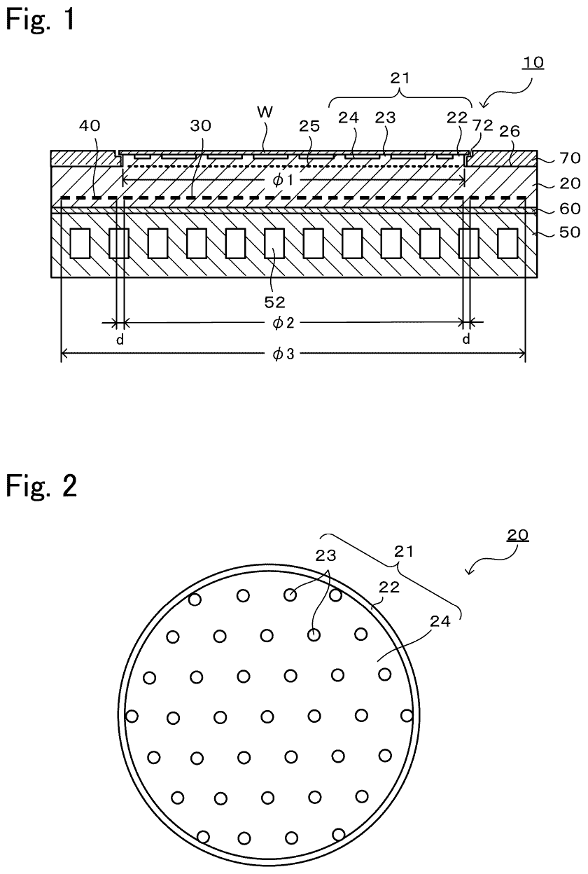

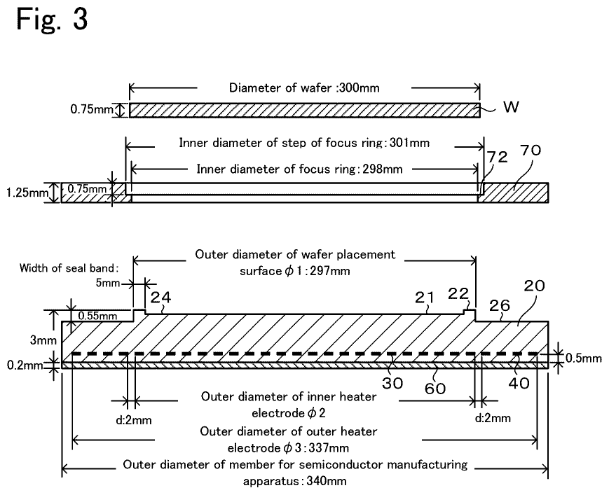

A preferred embodiment of the present invention will be described below with reference to the drawings. FIG. 1 is a vertical cross-sectional view of a member for semiconductor manufacturing apparatus 10, FIG. 2 is a plan view of a ceramic plate 20, and FIG. 3 is an explanatory view illustrating examples of dimensions of the components.

The member for semiconductor manufacturing apparatus 10 is a component that holds a wafer W during semiconductor manufacturing. The member for semiconductor manufacturing apparatus 10 includes a ceramic plate 20, a cooling plate 50, and a bonding layer 60.

The ceramic plate 20 is a disc (for example, having a diameter of 340 mm and a thickness of 3 mm) formed of ceramic, such as sintered alumina and sintered aluminum nitride. The ceramic plate 20 has a circular wafer placement surface 21 and an annular focus ring placement surface 26. Hereafter, the focus ring is abbreviated as “FR” in some cases. The inner heater electrode 30 and the outer heater electrode 40 are embedded in the ceramic plate 20.

The ceramic plate 20 has the wafer placement surface 21 at the middle. The wafer placement surface 21 has an annular seal band 22 along the outer periphery. As illustrated in FIG. 2, the wafer placement surface 21 has the seal band 22 along the outer edge and multiple small circular projections 23 in the entire area located inwardly from the seal band 22. The seal band 22 and the small circular projections 23 have the same height. The height is, for example, several to tens of micrometers. An area of the wafer placement surface 21 without the seal band 22 and the small circular projections 23 is called a reference surface 24. A wafer W is placed on the top surface of the seal band 22 and the top surfaces of the small circular projections 23. The outer diameter of the wafer W is slightly larger than the outer diameter φ1 of the wafer placement surface 21 (equal to the outer diameter of the seal band 22). An electrostatic electrode 25 is embedded in the ceramic plate 20 under the wafer placement surface 21. When a DC voltage is applied across the electrostatic electrode 25, the wafer W is attracted and fixed to the wafer placement surface 21 (specifically, the top surface of the seal band 22 and the top surfaces of the small circular projections 23) by the electrostatic attraction. When the application of a DC voltage is stopped, the attraction of the wafer W to the wafer placement surface 21 is released.

The FR placement surface 26 is located outside the wafer placement surface 21 and below the wafer placement surface 21 (the top surface of the seal band 22). The focus ring 70 is mounted on the FR placement surface 26. The focus ring 70 has a step 72 extending in the circumferential direction at the upper portion of the inner circumferential surface. The step 72 is provided to prevent contact between the focus ring 70 on the FR placement surface 26 and the wafer W.

The inner heater electrode 30 is provided in a circular area that substantially corresponds to the wafer placement surface 21 in plan view. The inner heater electrode 30 is a resistance heating wire arranged in a one-stroke pattern from one end to the other end in plan view without crossing over a virtual plane that is parallel to the wafer placement surface 21. The line width of the resistance heating wire is, for example, 2 mm, and the space width between the adjacent resistance heating wires is, for example, 2 mm. The outer diameter φ2 of the inner heater electrode 30 (the diameter of the circle that has the same center as the wafer placement surface 21 and defines the outer circumferential edge of the inner heater electrode 30) is not less than 97% of the outer diameter φ1 of the wafer placement surface 21, and preferably not less than 97% and not more than 103% of the outer diameter φ1. The inner heater electrode 30 overlaps at least a portion of the seal band 22 in plan view.

The outer heater electrode 40 is in an annular area that substantially corresponds to the FR placement surface 26 in plan view. The outer heater electrode 40 surrounds the inner heater electrode 30. The outer heater electrode 40 is a resistance heating wire arranged in a one-stroke pattern from one end to the other end without crossing over the same plane as the inner heater electrode 30. The line width of the resistance heating wire is, for example, 2 mm, and the space width between the adjacent resistance heating wires is, for example, 2 mm. The outer diameter φ3 of the outer heater electrode 40 (the diameter of the circle that has the same center as the wafer placement surface 21 and defines the outer circumferential edge of the outer heater electrode 40) is slightly smaller than the outer diameter of the ceramic plate 20. The distance d between the inner circumferential edge of the outer heater electrode 40 and the outer circumferential edge of the inner heater electrode 30 should not be particularly limited but is preferably in a range of, for example, 2 to 18 mm.

The cooling plate 50 is a disc having a high thermal conductivity (a disc having a diameter equal to or larger than that of the ceramic plate 20). The cooling plate 50 internally includes a refrigerant flow path 52 through which a refrigerant (such as an electrically insulating liquid such as a fluorine-based inert liquid) circulates. The refrigerant flow path 52 extends in a one-stroke pattern over the entire area of the cooling plate 50 from the inlet to the outlet in plan view. The material of the cooling plate 50 is, for example, a metal or a composite material. Examples of the metal include Mo, Al, and Al alloy. Examples of the composite material include metal matrix composites (Metal Matrix Composite (MMC)) and ceramic matrix composites (Ceramic Matrix Composite) (CMC). Specific examples of the composite materials include a material containing Si, SiC, and Ti and a material containing a SiC porous body impregnated with Al and/or Si. A material containing Si, SiC, and Ti is called SisiCTi, and a material containing a SiC porous body impregnated with Si is called SiSiC. The material of the cooling plate 50 is preferably a material having a coefficient of thermal expansion close to that of the material of the ceramic plate 20.

The bonding layer 60 bonds the lower surface of the ceramic plate 20 and the upper surface of the cooling plate 50 to each other. Examples of the bonding layer 60 includes a resin adhesive layer, such as a resin adhesive sheet. The resin adhesive layer has a thermal conductivity of, for example, 0.1 to 0.3 W/mK.

Although not illustrated in the drawings, the member for semiconductor manufacturing apparatus 10 has a gas supply passage through which a heat transfer gas (e.g., He gas) is supplied from the lower surface of the cooling plate 50 to the area of the wafer placement surface 21 that is surrounded by the seal band 22.

Next, an example of the use of the member for semiconductor manufacturing apparatus 10 will be described. The member for semiconductor manufacturing apparatus 10 is mounted in a chamber not illustrated in the drawings. Then, after the focus ring 70 is placed on the FR placement surface 26, a wafer W is placed on the wafer placement surface 21. Subsequently, the chamber is depressurized by a vacuum pump to a predetermined vacuum degree, and a DC voltage is applied across the electrostatic electrode 25 to generate an electrostatic attraction force. This allows the wafer W to be attracted and held by the wafer placement surface 21 (specifically, the upper surface of the seal band 22 and the upper surfaces of the small circular projections 23). In the refrigerant flow path 52 of the cooling plate 50, a temperature-controlled refrigerant is circulated. The temperature of the wafer W and the temperature of the focus ring 70 are controlled by adjustments of the power supplied to the inner heater electrode 30, the power supplied to the outer heater electrode 40, and the temperature of the refrigerant supplied to the refrigerant flow path. In the temperature control of the wafer W, a temperature detection sensor not illustrated in the drawings detects the temperature of the wafer W and provides feedback such that the temperature becomes a target temperature. In the temperature control of the focus ring, a temperature detection sensor not illustrated in the drawings detects the temperature of the focus ring and provides feedback such that the temperature becomes a target temperature. The space defined by the lower surface of the wafer W on the wafer placement surface 21 and the seal band 22 is filled with a heat transfer gas through a gas flow path not illustrated in the drawings. The presence of the heat transfer gas improves efficiency of heat transfer between the wafer W and the ceramic plate 20. Then, in this state, the wafer W is subjected to a process, such as CVD deposition or etching.

Although the focus ring 70 wears out due to the process on the wafer W, the focus ring 70 is thick and the focus ring 70 does not need to be replaced until multiple wafers W are subjected to the process.

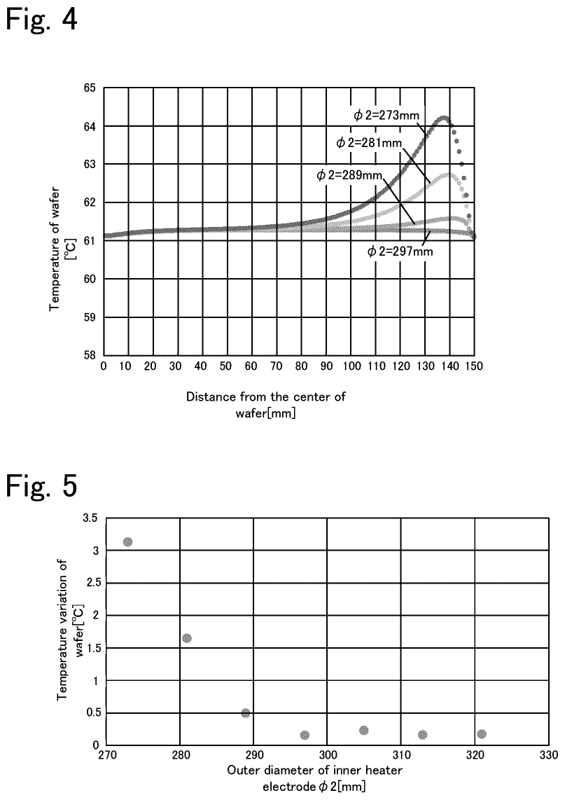

Next, a test was conducted to investigate how the outer diameter φ2 of the inner heater electrode 30 affects the heat uniformity of the wafer W. Dimensions of the components were as indicated in FIG. 3. The outer diameter φ2 was varied in a range of 273 to 321 mm. The wafer placement surface 21 had no small circular projections 23 but had the seal band 22. The resistance heating wire of the inner heater electrode 30 had the line width of 2 mm and the space width of 2 mm. The resistance heating wire of the outer heater electrode 40 also had the line width of 2 mm and the space width of 2 mm. The thermal conductivity of the bonding layer 60 was 0.2 W/mK, the thermal conductivity of each of the heater electrodes 30 and 40 was 30 W/mK, and the thermal conductivity of the space below the wafer W (space filled with He gas) was 0.05 W/mK. The wafer W and the focus ring 70 were formed of silicon (having a thermal conductivity of 163 W/mK), and the ceramic plate 20 was formed of alumina (having a thermal conductivity of 35 W/mK) . After that the target temperature of the wafer W was set at 60° C. and then the power supplied to the inner heater electrode 30 and the power supplied to the outer heater electrode 40 were controlled. FIG. 4 and FIG. 5 indicate the results of the test.

In the graph in FIG. 4, the horizontal axis indicates the distance from the center of the wafer W, and the vertical axis indicates the temperature of the wafer W. In the graph in FIG. 5, the horizontal axis indicates the outer diameter φ2 of the inner heater electrode 30, and the vertical axis indicates the temperature variation of the wafer W (difference between the lowest temperature and the highest temperature in an area between the center and the outermost periphery of the wafer W). FIG. 4 indicates the results of changes in φ2 in a range of 273 to 297 mm, and FIG. 5 indicates results of changes in φ2 in a range of 273 to 321 mm.

From FIGS. 4 and 5, it was found that when the outer diameter φ2 of the inner heater electrode 30 is not less than 289 mm (97% of the outer diameter ol of the wafer placement surface 21), the temperature variation of the wafer W can be sufficiently reduced. It was also found that when φ2 is not less than 297 mm (100% of φ1), the temperature variation of the wafer W can be further reduced. However, if φ2 is too large, the temperature of the focus ring 70 needs to be controlled by using both the inner heater electrode 30 and the outer heater electrode 40, requiring more complex control. If φ2 is kept not more than 103% of φ1, the temperature of the focus ring 70 can be controlled by the outer heater electrode 40 alone.

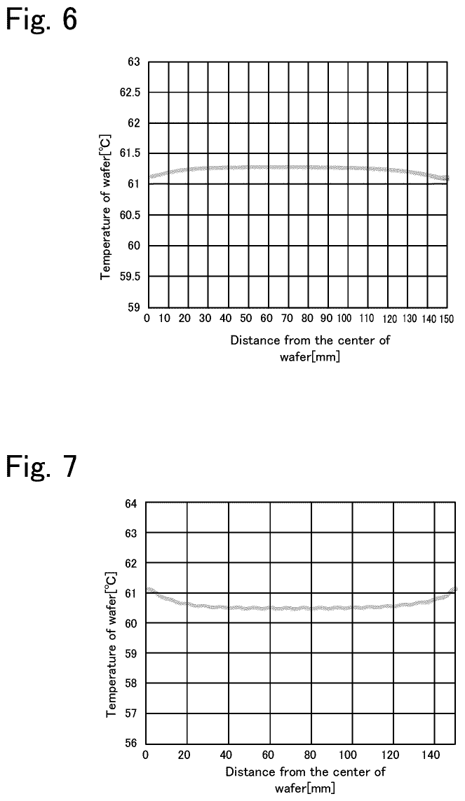

Furthermore, in FIG. 3, the temperatures of the wafers W were measured with φ2 being fixed at 297 mm, while the distance d between the outer circumferential edge of the inner heater electrode 30 and the inner circumferential edge of the outer heater electrode 40 being set at different values, 4 mm, 6 mm, 10 mm, and 18 mm. The distance d was varied by varying the inner diameter of the outer heater electrode 40. FIG. 6 indicates the results. In the graph in FIG. 6, the horizontal axis indicates the distance from the center of the wafer W, and the vertical axis indicates the temperature of the wafer W. In FIG. 6, the graphs for the distances d have substantially the same shape and overlap each other.

Furthermore, in FIG. 3, the temperatures of the wafers W were measured with φ2 being fixed at 297 mm, the line width of the resistance heating wire of the inner heater electrode 30 being fixed at 2 mm, and the space width being fixed at 6 mm, while the distance d being set at different values, 2 mm, 6 mm, 10 mm, and 18 mm. The distance d was varied by varying the inner diameter of the outer heater electrode 40. FIG. 7 indicates the results. In the graph in FIG. 7, the horizontal axis indicates the distance from the center of the wafer W, and the vertical axis indicates the temperature of the wafer W. In FIG. 7, the graphs for the distances d have substantially the same shape and overlap each other.

With reference to FIGS. 6 and 7, it was found that when the distance d is in a range of 2 to 18 mm, the temperature variation of the wafer W can be reduced. It was also found that the temperature variation of the wafer W can be reduced when L/S is in a range of ⅓ to 1 in which L is the line width of the resistance heating wire of the inner heater electrode 30 and S is the space width.

In the member for semiconductor manufacturing apparatus 10 described above, the inner heater electrode 30 overlaps at least a portion of the seal band 22 in plan view. Furthermore, the outer diameter 42 of the inner heater electrode 30 is not less than 97% of the outer diameter ol of the wafer placement surface 21. This can increase the temperature uniformity of the wafer placed on the seal band 22 of the wafer placement surface 21.

Furthermore, the outer diameter 42 of the inner heater electrode 30 is preferably between not less than 97% and not more than 103% of the outer diameter φ1 of the wafer placement surface 21. In this configuration, the inner heater electrode 30 does not largely overlap the FR placement surface 26 when viewed in plan view. Thus, the temperature of the focus ring 70 is not largely affected by the inner heater electrode 30, making it easier for the outer heater electrode 40 alone to control the temperature of the focus ring 70.

Furthermore, the distance d between the outer circumferential edge of the inner heater electrode 30 and the inner circumferential edge of the outer heater electrode 40 is preferably between not less than 2 mm and not more than 18 mm. This can reliably provide the effect of the present invention.

Furthermore, a resin adhesive layer may be disposed between the ceramic plate 20 and the cooling plate 50 as the bonding layer 60. In this case, the heat transfer from the ceramic plate 20 to the cooling plate 50 is limited by the resin adhesive layer, which has a relatively low thermal conductivity, but the temperature uniformity of the wafer W can be increased even under such a circumstance.

The present invention should not be limited to the above-described embodiment and may be implemented in various modes without departing from the technical scope of the present invention.

In the embodiment described above, the inner heater electrode 30 and the outer heater electrode 40 are embedded at a height of 0.5 mm from the lower surface of the ceramic plate 20, but this should not be construed as limiting. For example, the height may be suitably set in a range of not less than 0.5 mm and not more than 2 mm. This also can provide the same effect as the above-described embodiment.

In the above-described embodiment, the electrostatic electrode 25, the inner heater electrode 30, and the outer heater electrode 40 are embedded in the ceramic plate 20, but this should not be construed as limiting. For example, in addition to the above, RF electrodes for plasma generation may be incorporated.

In the above-described embodiment, a resin adhesive layer is described an example of the bonding layer 60, but this should not be construed as limiting. For example, a metal bonding layer may be employed instead of the resin adhesive layer.

International Application No. PCT/JP2022/046693, filed on Dec. 19, 2022, is incorporated herein by reference in its entirety.

What is claimed is:

1. A member for semiconductor manufacturing apparatus comprising:
a ceramic plate having
a circular wafer placement surface having a seal band along an outer periphery, and
an annular focus ring placement surface located outside the wafer placement surface and below the wafer placement surface;
a circular inner heater electrode embedded in the ceramic plate;
an annular outer heater electrode embedded in the ceramic plate and surrounding the inner heater electrode; and
a cooling plate disposed at a surface of the ceramic plate opposite the wafer placement surface, wherein
the inner heater electrode overlaps at least a portion of the seal band in plan view, and an outer diameter of the inner heater electrode is not less than 97% of an outer diameter of the wafer placement surface.

2. The member for semiconductor manufacturing apparatus according to claim 1, wherein the outer diameter of the inner heater electrode is not less than 97% and not more than 103% of the outer diameter of the wafer placement surface.

3. The member for semiconductor manufacturing apparatus according to claim 1, wherein a distance between an outer circumferential edge of the inner heater electrode and an inner circumferential edge of the outer heater electrode is not less than 2 mm and not more than 18 mm.

4. The member for semiconductor manufacturing apparatus according to claim 1, further comprising a resin adhesive layer between the ceramic plate and the cooling plate.
